(19) United States
(12) Patent Application Publication
(10) Pub. No.: US 2026/0334297 A1
(43) Pub. Date: Oct. 22, 2026

(54) SELF-CURING CONCRETE AS NEW MATERIAL FOR MICROSYSTEMS

(71) Applicant: Hahn-Schickard-Gesellschaft für angewandte Forschung e. V., Stuttgart (DE)

(72) Inventors: Achim Bittner, Heilbronn (DE); Alfons Dehé, Reutlingen (DE)

(21) Appl. No.: 19/105,711

(22) PCT Filed: Aug. 22, 2023
(86) PCT No.: PCT/EP2023/073007

§ 371 Date: Feb. 21, 2025

(30) Foreign Application Priority Data
Aug. 23, 2022 (EP) 22191632.3

(51) Int. Cl. H10W 74/40; B81B 7/00

(52) U.S. Cl. CPC H10W 74/40; B81B 7/0032

(57) ABSTRACT

The invention relates to a semiconductor component comprising a MEMS element and/or an electronic circuit, wherein the MEMS element and/or the electronic circuit is provided on or in a base substrate. The semiconductor component is characterized in that it exhibits a concrete material. Thus, one or more constituents of the semiconductor component may comprise the concrete material, such as the base substrate, an insulating layer and/or a protective enclosure. The invention also relates to a method for producing the semiconductor component.

The invention relates to a semiconductor component comprising a MEMS element and/or an electronic circuit, wherein the MEMS element and/or the electronic circuit is provided on or in a base substrate. The semiconductor component is characterized in that it comprises a concrete material. Thus, one or more components of the semiconductor component may comprise the concrete material, such as the base substrate, an insulating layer and/or a protective enclosure. The invention also relates to a method for producing the semiconductor component.

### BACKGROUND AND PRIOR ART

It is known that a large number of components can be constructed using semiconductor technology methods. Such components are also referred to as semiconductor components. In particular, semiconductor components can exhibit structures with sizes and dimensions in the micrometer range. If a mechanical microstructure is combined with an electrical circuit, this is also referred to as a MEMS (microelectromechanical system), MEMS device, MEMS system or MEMS element.

MEMS elements can combine logic elements and micromechanical structures on one chip. Due to their ability to process and/or generate mechanical and electrical signals, they are suitable for a wide range of applications, such as sensors, actuators, filters and/or oscillators.

At the present time, MEMS elements form an important technical basis for solutions in microelectronics. Compared to conventional macrosystems, they offer advantages above all in terms of cost savings due to the low consumption of materials and/or the possibility of parallel production, as well as in terms of efficiency, which is made possible by lower energy and power requirements

The choice of material for the components of a semiconductor component is a relevant factor for its functionality and the production method. In this respect, various materials with individual advantages have proven to be effective in the prior art.

Fedder (2003) provides an overview of known materials for micromechanical applications, classifying them into five main categories, namely structural materials, substrate materials, spacer materials, surface materials and active materials. The structural material and the substrate material, which can be one and the same, must be able to withstand different process steps. The relevant properties of the structural material include the modulus of elasticity, density, residual stress and stress gradients, electrical and thermal conductivity and the long-term stability of these properties. Spacer materials are usually etched away in whole or in part to expose the microstructure and are often referred to as sacrificial materials or sacrificial layers due to this function. Spacer materials can also be used to produce molds for structures. Surface materials or insulation materials can be used to protect the substrate or structural material from certain etching steps. Surface materials are also important to achieve electrical insulation. Active materials are applied to structures to utilize their particular physical properties or effects in order to generate and/or read out a signal. Common physical properties and/or effects that are utilized are piezoelectric effects.

In the context of microsystems technology, silicon and/or gallium arsenide are frequently used as materials for (base) substrates. Said materials have proven effective in particular in that sensor elements and/or actuator elements can be provided from the material. Furthermore, silicon and gallium arsenide are comparatively inexpensive as semiconductor materials and can be fabricated and/or packaged using established processes. In particular, their electrical conductivity can be significantly improved by doping. With regard to the possibilities for improving the function of a semiconductor component in terms of the selection and/or processing of semiconductor materials, reference can be made to Rahman (2014).

Other materials such as quartz, Pyrex, polymers, ceramics and/or plastics can also be used as substrates in semiconductor technology and/or microsystems technology. Such materials can also be used as so-called packaging substrates or package substrates to enable the encapsulation of MEMS elements and thus ensure particularly good protection.

Likewise, with regard to insulation materials or insulation layers, various materials have proven to be effective. The dielectric materials used for this purpose are used in particular to provide insulation for electronic contacts and/or to protect the MEMS element and/or an electronic circuit from undesirable electrical effects. One known insulating material is silicon dioxide. The selection of dielectric materials can be decisive for the functionality of the semiconductor component, as this can influence parasitic capacitances and/or inductances, for example. It is particularly relevant in the field of high-frequency applications to reduce parasitic capacitances. The prior art approach here is to reduce the permittivity of the dielectric material, for example by using so-called low-k materials (see also Shamiryan et al. (2004)).

Encapsulation by a capping substrate (also known as wafer capping) has proven to be particularly useful for providing a housing to protect a MEMS element and/or an electronic circuit. Substrate materials such as silicon can also be used. The capping substrate is used to protect a MEMS element and/or an electronic circuit. For this purpose, the capping substrate is connected to the base substrate, i.e. the substrate exhibiting the MEMS element and/or the electronic circuit, for example by bonding. This makes it possible to create a desired pressure within the encapsulant, e.g. a vacuum, such that a hermetic or almost hermetic seal can be achieved (see also Heakyoung (2013)).

It is known that, in addition to the electrical or dielectric requirements, certain mechanical and/or thermal requirements of the materials for constituents of the semiconductor component must also be met in order to ensure optimum operation. In particular, reliable protection and a long service life of the semiconductor component should also be ensured. The semiconductor component should be able to withstand vibrations and not undergo any significant expansion due to thermal effects, in order that that no structural changes are caused.

The electrical, dielectric and mechanical properties of the constituents of a semiconductor component can be optimized by the chemical structure, the processing-related morphology and the fillers and/or reinforcing agents used for the materials.

However, there are also some disadvantages with regard to known materials and production processes for semiconductor components. For example, in order to carry out processing operations on constituents of semiconductor components and/or MEMS elements, chemical reactions often have to be induced in the actual production process, e.g. to achieve hardening of a composition. Such chemical reactions often require the application of heat (e.g. by means of a laser or oven), which makes the method more complex and cost-intensive. Furthermore, certain materials and/or constituents of a semiconductor component and/or a MEMS element may be subject to critical temperatures—for example of approx. 130 °C—which should not be exceeded in order to avoid undesirable structural changes.

A further difficulty exists with regard to the shaping of constituents of the semiconductor components, in particular when using materials such as glasses and/or single crystals, which are of high quality, for example, but cannot be optimally shaped structurally during a production process. Other materials that may be easier to shape, such as polymers and/or ceramics in the context of additive manufacturing, may produce an impaired hermetic seal due to inhomogeneities, which could reduce the service life of the semiconductor component.

Consequently, there is a need in the prior art to provide semiconductor components with improved material properties.

### OBJECTIVE OF THE INVENTION

The objective of the invention was to eliminate the disadvantages of the prior art. In particular, one objective of the invention was to provide semiconductor components or methods for their production which are characterized by optimized functionality, high economic efficiency and process-efficient and cost-effective production.

### SUMMARY OF THE INVENTION

The objective of the invention is solved by the independent claims. Advantageous embodiments of the invention are disclosed in the dependent claims.

In a first aspect, the invention relates to a semiconductor component comprising a MEMS element and/or an electronic circuit, wherein the MEMS element and/or the electronic circuit is provided on or in a base substrate, characterized in that the base substrate comprises a concrete material, the semiconductor component exhibits an insulating layer comprising concrete material for insulating an electrical connection and/or the MEMS device and/or the electronic circuit is at least partially enclosed by a protective enclosure comprising concrete material.

The inventors have recognized that the use of concrete material can surprisingly significantly improve both the structural and functional properties of a semiconductor component. In particular, it has been recognized that a variety of desirable effects can be achieved and combined by using concrete material, which are of particular benefit in the production of semiconductor components and to the semiconductor components as such.

For this purpose, it is provided according to the invention that at least one constituent of the semiconductor component comprises a concrete material. Preferably, a plurality of components can also comprise a concrete material. Preferably, the base substrate, the insulating layer (synonymously also insulation layer) and/or the protective enclosure comprise a concrete material.

By using concrete material for the base substrate, for example, a particularly homogeneous surface can be advantageously achieved. Furthermore, the smoothness of the surface of the base substrate can be adjusted both precisely and easily. In addition, it is advantageous that further functional materials, such as metals for the provision of conductor paths, can be provided on the base substrate comprising concrete material in a process-efficient manner. Furthermore, a reliable connection with the MEMS element and/or the electronic circuit is advantageously ensured if this is to be applied to the base substrate.

An insulating layer comprising concrete material also has advantages for the semiconductor component. Concrete material is dielectric, such that protection against charge transfer and/or charge equalization is guaranteed. Furthermore, the ease with which concrete material can be shaped, and in particular structured, as an insulating layer is particularly useful, as the electrical and dielectric properties of the semiconductor component can be optimally adjusted by means of the structure of the insulating layer. For example, with an insulating layer comprising concrete material, pores can be introduced with little effort, which can be configured to reduce parasitic capacitances.

Concrete material has also proven to be advantageous for providing a protective enclosure. In particular, the concrete material can ensure that the MEMS element and/or the electronic circuit is hermetically sealed. As a result, an exchange of substances between the environment and internal constituents of the semiconductor component is advantageously prevented and a long-lasting functional capability of the semiconductor component is achieved.

The use of concrete material has proven to be advantageous not only structurally, but also for processes or methods for producing the semiconductor component or individual constituents of the semiconductor component.

It is to be emphasized as being particularly advantageous that the self-hardening property of the concrete material can be used to produce constituents of the semiconductor component. Self-hardening means in particular that the concrete material can be hardened without the need for an additional external energy supply. This advantageously results in considerable process efficiency, as simple shaping can be achieved and no further effort is required for the hardening reaction.

The self-hardening of the concrete material is preferably based on cement (as a binder). Hardening, also known as setting, preferably corresponds to a slow chemical-mineralogical reaction of the cement with water, wherein water is also a preferred constituent of the concrete material. The cement is preferably a hydraulic binder that only hardens when water is added. The hardening of the concrete material is based, inter alia, without being limited to theory, on hydration as a chemical reaction, which will be discussed in more detail below. Cement and water as constituents of the concrete material are therefore decisive for hardening, rather than the aggregates.

The possibility of utilizing the self-hardening of concrete material also advantageously ensures that no high temperatures occur which could lead to undesirable structural changes in the semiconductor component. In particular, it is avoided that a temperature has to be applied which could be critical for the functionality of constituents and/or materials of the semiconductor component and/or the MEMS element, for example a temperature of approx. 130 °C.

Another advantage is that concrete material can be combined with a variety of substances for a desired reaction. For example, it is particularly easy to integrate metals into the concrete material in order to provide conductive paths for electrical contacts. Furthermore, concrete material's alkaline property can be used advantageously in the context of processing, for example for in-situ conditioning of surfaces. Furthermore, an alkaline environment of the concrete material is advantageous in that a particularly high degree of strength can be achieved through the reaction of the cement with water.

According to the invention, it has thus been recognized that a number of advantageous technical effects are achieved by using concrete material to produce a semiconductor component, which have an advantageous effect both on the processing and on the semiconductor component as such.

For the purposes of the invention, a semiconductor component preferably refers to a component which is used for circuits in electrical engineering or electronics, in particular in connection with semiconductor materials. The average person skilled in the art knows that the term semiconductor component can be interpreted broadly. For example, a semiconductor component may comprise an integrated circuit which exhibits transistors and/or diodes or may itself be such a component. Preferably, the integrated circuits are produced on base substrates. In addition, components such as transistors, diodes and/or capacitors can be produced by processing the base substrate. A plurality of base substrates may also be used, which can then be divided up and form a plurality of chips. A semiconductor component may also comprise or itself be, for example, a printed circuit board, a plurality of processors, semiconductor memories, microcontrollers, transducers, microchips, etc. A semiconductor component can preferably be produced using methods and/or equipment from semiconductor and/or microsystems technology.

Preferably, the semiconductor component comprises a base substrate, an insulating layer and/or a protective enclosure. Furthermore, it is preferred that the semiconductor component exhibits a MEMS element and/or an electronic circuit. The base substrate is preferably to be understood as the carrier of the MEMS element and/or the electronic circuit. It may also be preferred that the MEMS element and/or the electronic circuit is present within the base substrate. For this purpose, it may be preferred to incorporate MEMS structures into the base substrate, for example by using etching processes. Therefore, it may also be preferred that the MEMS element is part of the base substrate.

An insulating layer is preferably a layer that enables electrical insulation, for example of electrical contacts. Dielectric intermediate layers can also preferably be regarded as insulating layers in the context of the invention.

An intermediate layer as an insulating layer preferably means a dielectric layer present between at least two constituents and/or at least two sections of the semiconductor component. For example, it may be preferred that the intermediate layer is provided between two substrates in order to enable electrical insulation between these two substrates. The intermediate layer preferably has a planar configuration, i.e. it preferably has a length and/or width that is many times greater than its thickness, preferably by a factor of 1.5, 2, 3, 4, 5, 6, 7, 8, 9, 10 or more.

The protective enclosure is preferably used to enclose the MEMS element and/or the electronic circuit in order to prevent an exchange of substances with the environment. For this purpose, it is preferred that the protective enclosure is applied at least partially over the MEMS element and/or the electronic circuit, preferably completely.

As explained above, it was recognized in accordance with the invention that the use of a concrete material can offer various advantages for providing a base substrate, an insulating layer and a protective enclosure. Such use of concrete material for the production of semiconductor components is not known from the prior art.

The aforementioned preferred constituents can be constituent elements of the semiconductor component according to the invention either individually or in combination with each other. Thus, the semiconductor component preferably comprises a base substrate, a protective enclosure and/or an insulating layer. Accordingly, it may be preferred that the semiconductor component comprises only the base substrate, the protective enclosure or the insulating layer, preferably in combination with a MEMS element and/or an electronic circuit. It may also be preferred that the semiconductor component comprises the base substrate and the protective enclosure, or the base substrate and the insulating layer, or the protective enclosure and the insulating layer, or the base substrate and the protective enclosure and the insulating layer, preferably in combination with a MEMS element and/or an electronic circuit.

In the context of the invention, concrete material preferably means a material which comprises concrete in its chemical composition, preferably meaning concrete as a building material. In particular, concrete comprises a binder for generating chemical bonds and an aggregate for imparting stability and/or strength.

In a preferred embodiment, the semiconductor component is characterized in that the concrete material comprises a cement, wherein preferably the cement is selected from a group comprising granulated blast furnace slag, silica fume, pozzolana, fly ash, burnt shale, lime, calcium sulphate, torrefied cement clinker and/or cement clinker, wherein preferably the cement clinker comprises tricalcium silicate, dicalcium silicate, tricalcium aluminate, tetracalcium aluminate ferrite, tricalcium aluminate and/or free calcium oxide.

The cement is an essential component of the concrete material and is preferably a binding agent that results in the setting process. The setting process refers to the chemical reaction during which the concrete material self-hardens. In particular, cement is a hydraulic binder, i.e. the concrete material can harden both in air and under water and is also resistant. During hardening, i.e. during the setting process, the cement reacts with water to form insoluble, stable compounds. These compounds, which can be present as calcium silicate hydrates, for example, form fine needle-shaped crystals which interlock with each other and thus lead to the high strength of the cement and therefore the self-hardening of the concrete material. Hydration, i.e. the accumulation of water molecules, takes place during the self-hardening process.

Cement clinker refers to a solid substance that forms part of the cement, in particular Portland cement, wherein the Portland cement can be provided by cement clinker and lime or anhydrite. Portland cement comprises approx. 58-66% calcium oxide, approx. 18-26% silicon dioxide, approx. 4 to 10% aluminum oxide and 2-5% iron oxide. The cement clinker in particular is responsible for the self-hardening by means of hydration, wherein this, without wishing to be limited to one theory, in turn results from the chemical structure of tricalcium silicate, dicalcium silicate, tricalcium aluminate, tetracalcium aluminate ferrite, tricalcium aluminate and/or free calcium oxide. In the prior art, the terms silicate reaction and aluminate reaction are also commonly used for this.

The aforementioned types of cement have proven to be advantageous for the rapid and reliable utilization of the self-hardening of the concrete material. In addition, hydroxide ions can form on contact with water, i.e. the concrete material is alkaline. The hydroxide ions formed on contact with water can be used, for example, to adjust the nucleophilicity in order to induce a desired chemical reaction, particularly during processing.

In a preferred embodiment, the semiconductor component is characterized in that the concrete material is a fiber-reinforced concrete comprising fibers, wherein the fibers preferably comprise a material selected from a group comprising plastic, steel and/or glass.

Fiber-reinforced concrete preferably refers to a concrete material that exhibits fibers and thus contains a fiber reinforcement. The fibers can be plastic, steel and/or glass fibers, for example. In the case of fiber reinforcement, the matrix is preferably selected from a group comprising cement, cement stone and/or mortar.

With the help of introduced fibers, (tensile) stresses of the concrete material can be absorbed advantageously, such that a particularly pronounced strength, stability and/or hardness can be achieved. This is particularly useful for the base substrate and/or the protective enclosure, for example, in order to improve the protective function. For example, a protective effect is also provided if the semiconductor component is exposed to mechanical stresses such as vibrations or similar.

Advantageously, further properties for the concrete material and thus the semiconductor component can be adjusted by parameters of the fiber. Parameters for the fibers (also known as fiber properties) can be selected from a group comprising fiber materials (preferably plastic, steel and/or glass), fiber sizes (e.g. micro and/or macro fibers) and/or fiber geometries (e.g. straight, hook-shaped, undulating, end-crimped and/or end-compressed). The fiber properties can be used to regulate the mechanical, electrical, optical properties and/or the behavior when exposed to foreign substances. Furthermore, the processing properties and/or the usage properties of the concrete material for the semiconductor component can be additionally optimized by means of the fiber properties.

In a preferred embodiment, the semiconductor component is characterized in that the concrete material exhibits a pore structure, wherein the pore structure preferably exhibits pores with a diameter selected between 1 nm-200 nm, preferably between 2-50 nm, particularly preferably between 5 nm-40 nm

The presence of a pore structure for the concrete material is particularly advantageous for the insulating layer of the semiconductor component. In this way, parasitic capacitances between two or more conductive sections, e.g. conductor paths or vias, can be reduced. The formation of parasitic capacitances is a well-known problem in semiconductor and microsystems technology. Inter alia, parasitic capacitances occur when two or more conductive regions with different voltages are close to each other, such that the electrical field between them stores an electric charge on them. The effect of parasitic capacitance is particularly relevant in high-frequency applications. Advantageously, the pore structure of the concrete material can reduce the material density and thus the dipole density, in particular for the insulating layer. This reduces the relative permittivity and therefore also the parasitic capacitance. It is thus advantageously possible to create a desired pore structure of the concrete material in a simple way. In particular, the pore structure can be easily and precisely adjusted using the method by which the concrete material can be applied. The aforementioned preferred ranges for pore diameters have proven to be particularly useful for reducing parasitic capacities.

In a preferred embodiment, the semiconductor component is characterized in that the concrete material exhibits a roughness, wherein the roughness preferably exhibits a mean roughness value in a range between 0.01 μm and 100 μm, preferably between 1 μm and 50 μm, particularly preferably between 5 μm and 20 μm

The term roughness is preferably used to describe the unevenness of a surface, in particular the surface height. The average roughness value preferably describes a parameter that can be used to characterize the roughness of a surface. The lower the average roughness value, the less rough and the smoother the surface. The aforementioned average roughness values have proven to be advantageous in order to provide sufficiently smooth surfaces for the functionality of the semiconductor component. A smooth surface is particularly advantageous for the base substrate and/or for the protective enclosure.

For the base substrate, the smoothness, in particular based on the aforementioned preferred average roughness values, is advantageous in that further coatings can also be applied smoothly. This advantageously eliminates the need for complex process steps, such as planarization, for example to make insulating layers and/or other layers sufficiently smooth.

A smooth surface is advantageous for the protective enclosure in that it prevents adhesion when it comes into contact with a foreign substance, e.g. a liquid. In addition, bonding with the concrete material, such as gluing, can be advantageously prevented or the protective effect of the protective enclosure can be reinforced.

In a preferred embodiment, the semiconductor component is characterized in that the base substrate exhibits the concrete material, wherein the MEMS element and/or the electronic circuit is present on a surface of the base substrate and/or is integrated into the base substrate.

For the purposes of the invention, the base substrate preferably refers to a flat, preferably disk-shaped body whose width and/or length is significantly greater than the thickness of the body. The length and/or width of the base substrate can be higher than the length and/or width by a factor of 1.5, 2, 3, 4, 5 or more. The thickness of the base substrate can be in the millimeter or submillimeter range, for example. The base substrate preferably serves as a carrier for the MEMS element and/or the electronic circuit.

Preferably, the base substrate comprises a concrete material. Advantageously, the surface properties of the base substrate can be precisely adjusted by using concrete material. In particular, a permanent connection between the base substrate and the electronic circuit and/or MEMS element can be advantageously achieved through adhesion if it is to be attached to the base substrate. In addition, the roughness or smoothness of the surface can be advantageously optimized such that further layers applied to the base substrate can also be configured to be substantially homogeneous.

In addition, the ease of processing concrete material makes it easy to obtain a desired shape for the base substrate. For example, the base substrate can exhibit a geometric shape that is round or angular in cross-section. For this purpose, it may be preferred to introduce the concrete material into a shaping component, wherein the shaping component can preferably act as a matrix for the shape. For shaping the base substrate, it may also be preferred to define parameters of a method by which the concrete material is applied and thus directly obtain a shape for the base substrate. Preferably, the concrete material is applied as a paste and the self-hardening of the concrete material is used to determine the shape of the base substrate.

Advantageously, the degrees of freedom with which the shape of the base substrate can be determined are easier to define than for other common materials used for base substrates in semiconductor and/or microsystems technology. For example, bevels, recesses and/or cavities can be introduced into the base substrate particularly easily. The ease of shaping resulting from the use of concrete material is also present for components such as insulating layers and/or protective enclosures.

The base substrate can preferably also exhibit a concrete material if the base substrate exhibits an SOI structure. An SOI structure is known in the prior art as a structure for substrates which exhibit a dielectric oxide layer between two semiconductor layers. Thus, it may be preferred that the base substrate comprising concrete material exhibits a first layer of concrete material, a dielectric layer positioned thereon and a second layer of concrete material positioned thereon.

The base substrate comprising concrete material can preferably also be present as a circuit carrier, preferably also as an injection-molded interconnect device (MID). Advantageously, the base substrate can be structured with a high degree of design freedom and exhibit the integration of electrical connections, such as conductive paths and/or vias, such that a significantly miniaturized semiconductor component can be provided.

The configuration of the base substrate comprising concrete material as a packaging substrate is also advantageously possible. A packaging substrate can advantageously provide a carrier and at the same time a protective enclosure for a MEMS element and/or an electronic circuit. For this purpose, it is preferred that the packaging substrate exhibits indentations into which the MEMS element and/or the electronic circuit can be inserted. Above the indentations, covers are preferably present which at least partially surround the MEMS element and/or the electronic circuit as a protective enclosure.

The use of concrete material therefore makes it possible to imitate known structures for the base substrate and optimize their properties.

Furthermore, MEMS structures for the MEMS element are particularly easy to incorporate into the base substrate. MEMS structures preferably refer to sections in the micrometer range (e.g. 1 μm 1000 μm) and are used to provide the MEMS element. MEMS structures are preferably introduced into the base substrate in order to integrate MEMS elements into the base substrate. It may also be preferred to form one or more cavities in the base substrate in order to create a free volume in which the MEMS element and/or the electronic circuit can be inserted. The advantage of this is that the semiconductor component can be highly compact and sensitive MEMS elements can be protected at the same time.

The use of concrete material for the base substrate has proven to be particularly advantageous, in particular for the geometric configuration and/or for the insertion of structures, such as MEMS structures and/or cavities. Due to the effect of self-hardening, structures for the base substrate can be present without having to apply a highly complex process. For example, no etching process is required to form the structures or cavities. Instead, a desired shape and/or structure can preferably already be provided during the provision of the base substrate by means of a corresponding shaping component by means of a setting process, e.g. in order to achieve hardening and/or strength at room temperature.

Advantageously, by using concrete material for the base substrate, different MEMS structures can be easily introduced to provide the MEMS element. The MEMS structures can be selected from a group comprising translatable, rotatable, vibratable, lamellar and/or meandering MEMS structures. Advantageously, many MEMS structures can thus be provided to form the MEMS element. Preferably, an electronic contact is also provided with the MEMS element in order to generate signals on the MEMS element or to read signals from the MEMS element. Thus, advantageously, a large number of MEMS structures can be introduced into the base substrate comprising concrete material, so that a large number of MEMS elements can be present on or in the base substrate.

In a further preferred embodiment, the semiconductor component is characterized in that the base substrate comprises a concrete material and an additive, wherein preferably the additive can be activated by an ablation process to form active regions and the active regions can be used by metallization to provide for the electrical connection of the MEMS element and/or the electronic circuit.

The additive preferably refers to a further additional substance present in or on the base substrate. The additive can preferably be selected from a group comprising aluminosilicates, preferably tectoaluminosilicates. It is known that aluminosilicates exhibit a pore structure. The aluminosilicates, which are preferably introduced into the concrete material as an additive, can be activated by the ablation process such that a metal, e.g. a precious metal, can accumulate in the pores of the pore structure. An electroless metallization can then preferably be carried out, in which metal is also deposited in an outer edge area of the pores, starting inside the pores. As a result, a planar metallization layer can be precisely formed on the surface of the base substrate

The ablation process is preferably a process that makes it possible to activate the additive. Activation preferably refers to a state in which a reaction, for example bonding with a metal, is facilitated. The ablation process can be carried out, for example, by the emission of electromagnetic radiation, in particular by laser beams. The metallization, i.e. the application of metal, can be carried out in a chemically reductive metal bath, e.g. in a copper bath.

Concrete material is advantageously suitable as an appropriate carrier for such an additive, in order to carry out metallization using an ablation process such that an electrical connection can be provided for the MEMS element and/or the electronic circuit.

In a preferred embodiment, the semiconductor component is characterized in that the insulating layer comprises a concrete material, wherein preferably the insulating layer is at least partially present on the electrical connection and/or encases an electrical connection.

The electrical connection can, for example, be selected from a group comprising conductor paths, conductor path levels and/or vias. Advantageously, concrete material as a dielectric material can be adapted to the shape of the electrical connection in order to ensure optimum electrical insulation. The concrete material can also preferably be optimally applied to bonding wires in order to provide insulation for electrical contacts between, for example, the MEMS element and the electronic circuit.

In a preferred embodiment, the semiconductor component is characterized in that the insulating layer comprises a concrete material, wherein the insulating layer preferably exhibits a pore structure.

A pore structure can advantageously improve the functionality of the semiconductor component. As explained above, the presence of a pore structure can, for example, reduce parasitic capacitances between electrical connections. One of the reasons for this is that the pore structure comprising pores reduces the dipole density.

In a preferred embodiment, the semiconductor component is characterized in that the protective enclosure is selected from a group comprising a protective layer and/or a capping substrate.

The aforementioned preferred options comprising a protective layer and/or a capping substrate have proven effective for enabling secure hermetic sealing of the MEMS element and/or the electronic circuit and thus provide reliable protection from the environment. It is advantageous to use concrete material for both a protective layer and a capping substrate.

In a preferred embodiment, the semiconductor component is characterized in that the semiconductor component exhibits a protective layer comprising concrete material, wherein the protective layer is preferably present on the MEMS element and/or the electronic circuit in conformity with the surface.

The protective layer preferably refers to a layer that can be applied to constituents of the semiconductor component, such as the MEMS element and/or the electronic circuit. By using concrete material, it is advantageously possible to apply the protective layer particularly precisely, such that local coverings are also possible.

In particular, it is advantageously possible to apply a protective layer comprising concrete material to the constituents of the semiconductor component in a manner that conforms to the surface. A protective layer that conforms to the surface refers in particular to a layer that lies substantially directly and closely against the underlying constituents while retaining their shape. Substantially directly and closely means preferably that the protective layer is mainly in direct contact, but in some regions does not include volumes filled by constituents, for example in corner regions or below a wire bond.

The surface-conformal protective layer preferably conforms completely to the surface. This means in particular that the protective layer is almost perfectly closely fitting or surface-conformal and that even the smallest structures are closely coated. The smallest structures are preferably structures with dimensions a maximum of 10 nanometers (nm), a maximum of 100 nm, a maximum of 1 micrometer (μm), a maximum of 10 μm or a maximum of 100 μm. On the one hand, by applying a surface-conformal protective layer comprising concrete material, a hermetic, space-optimized protective layer can be applied extremely cost-effectively. On the other hand, a surface-conformal protective layer allows a high degree of flexibility with regard to a precise opening or recess in the protective layer in an interaction region of the MEMS element. A MEMS interaction region preferably refers to a functional component of the MEMS element that interacts with an external medium in the desired manner. In the case of an acoustic MEMS transducer, for example, this is a MEMS membrane. In the case of an optical MEMS transducer, for example, it is an optical emitter.

The protective layer, which can preferably be present on the surface, preferably exhibits a thickness of approx. 10 nm (nanometers)-1 mm (millimeter). It may also be preferable for the protective layer to exhibit a thickness of approx. 10 nm-100 nm, approx. 100 nm-200 nm, approx. 200 nm-500 nm, approx. 500 nm-1 μm (micrometer), approx. 1 μm-5 μm, approx. 5 μm-10 μm, approx. 10 μm-50 μm, approx. 50 μm-100 μm, approx. 100 μm-500 μm or even approx. 500 μm-1 mm. A person skilled in the art will recognize that the aforementioned range limits can also be combined to obtain further preferred ranges, such as approx. 100 nm-1 μm, approx. 500 nm-5 μm or approx. 200 nm-10 μm.

The preferred thicknesses for the protective layer advantageously entail excellent protection of the MEMS element and/or the electronic circuit while at the same time being compact and ensuring high functionality. Furthermore, the preferred thicknesses for the protective layer can be provided simply, inexpensively and quickly using processes that have proven effective in the prior art.

Terms such as substantially, approximately, about, approx. etc. preferably describe a tolerance range of less than ±20%, preferably less than ±10%, even more preferably less than ±5% and in particular less than ±1%. Statements using substantially, approximately, about, approx. etc. always disclose and include the exact value mentioned.

In a preferred embodiment, the semiconductor component is characterized in that the semiconductor component exhibits a capping substrate comprising concrete material, wherein the capping substrate preferably covers the MEMS element and/or the electronic circuit and is bonded to the base substrate.

The capping substrate preferably refers to a substrate with which the MEMS element and/or the electronic circuit can be covered or enclosed. The capping substrate can preferably be an ordinary substrate or an SOI wafer comprising concrete material. Advantageously, a capping substrate comprising concrete material can be bonded to the base substrate such that a stable connection between the base substrate and the capping substrate is made possible. This provides particularly good protection for components on or in the base substrate. A material bond comprises bonds in which the base substrate and the capping substrate are held together by atomic or molecular forces. Materially bonded connections are also non-detachable connections that can only be separated by destroying the connecting means.

The capping substrate may preferably have substantially the same structure as the base substrate. In particular, it may preferably be the case that the capping substrate is substantially planar in shape, i.e. a length and/or width of the capping substrate is many times greater than a height of the capping substrate, preferably by a factor of at least 1.5, 2, 3, 4, 5, 6, 7, 8, 9, 10 or more. Furthermore, the capping substrate and/or the base substrate may preferably exhibit a cavity, wherein the capping substrate and the base substrate are preferably connected to one another in such a way that a cavity is formed within the semiconductor component, in which the MEMS element and/or the electronic circuit is preferably placed. The base substrate can preferably be connected to the capping substrate at lateral regions of the base and capping substrates which enclose one or both cavities. In this way, a cost-effective, compact and robust semiconductor component can be advantageously provided by simple means, within which a MEMS element and/or an electronic circuit can be placed in a protected position.

Due to the ease with which concrete material can be shaped, it is also advantageously possible to incorporate structures such as bevels, notches, indentations, grooves or other structures on the capping substrate. This advantageously enables optimum adaptation to a spatial volume for the semiconductor component. Consequently, the use of concrete material provides significantly improved design freedom for the semiconductor component as a whole.

In a preferred embodiment, the semiconductor component is characterized in that the MEMS element is selected from a group comprising an acoustic MEMS transducer, optical MEMS transducer, MEMS sensor, in particular MEMS gas sensor and/or MEMS filter.

Advantageously, reliable operational suitability and optimum usability can be ensured for a large number of MEMS elements if at least one constituent of the semiconductor component comprises a concrete material. For example, it may be preferred that the MEMS structures for providing the MEMS element comprise a concrete material. It may also be preferred that one or more insulating layers comprise a concrete material, which in particular enables secure electronic insulation. Furthermore, it may be preferred that the protective enclosure comprises a concrete material, such that reliable protection for the MEMS element is enabled.

A MEMS transducer preferably refers to a MEMS element that is capable of converting energy from one form to another. In particular, the input signal of a MEMS transducer differs from the output signal in terms of the type of signal.

Preferably, the MEMS transducer is selected from a group comprising an acoustic MEMS transducer and/or an optical MEMS transducer.

An acoustic MEMS transducer is configured to interact with a volume flow of a fluid, wherein the MEMS structures are configured to interact with the volume flow or to receive or generate pressure waves. The fluid can be either a gaseous or a liquid fluid

An acoustic MEMS transducer refers to a MEMS transducer that uses an acoustic signal, preferably sound pressure waves, during a conversion of a form of energy and/or a type of signal. This means that either the input signal or the output signal of an acoustic MEMS transducer is an acoustic signal. For example, an acoustic MEMS transducer can be a MEMS loudspeaker or a MEMS microphone. A MEMS loudspeaker, for example, is configured to generate an acoustic signal from an electrical signal. A MEMS microphone, for example, is configured to generate an electrical signal from an acoustic signal.

An optical MEMS transducer refers to a MEMS transducer in which the input signal or the output signal is an optical signal. An optical signal preferably refers to light, which can have a wavelength in the visible or non-visible range. For example, an optical MEMS transducer can convert light as an input signal into an electrical signal. For example, in an optical MEMS transducer, light can fall on an electrode surface and electrons can be emitted from the electrode surface. It is also possible, for example, that the resistance of a material in an optical MEMS transducer changes when it is illuminated. Furthermore, the operating principle may be such that an output voltage proportional to the radiation intensity is generated. Light can also be emitted based on an electrical variable in an optical MEMS converter, for example, such as in an OLED, LED, electroluminescent lamp, etc.

In further preferred embodiments, the MEMS element is a MEMS sensor, in particular a MEMS gas sensor and/or MEMS filter.

A MEMS sensor can, for example, comprise a capacitively or optically readable, piezoelectric, piezoresistive and/or magnetic bar and/or a capacitive, piezoelectric, piezoresistive and/or optical microphone or membrane for detecting a physical, chemical and/or biological variable.

Preferably, the MEMS sensor is a MEMS gas sensor. A MEMS gas sensor is preferably capable of detecting a gas as such and/or a concentration of a gas. A MEMS gas sensor can, for example, be based on the principle of photoacoustic spectroscopy. In photoacoustic spectroscopy, intensity-modulated infrared radiation with frequencies in the absorption spectrum of a molecule to be detected in a gas is preferably used. If this molecule is present in the beam path, modulated absorption takes place, which leads to heating and cooling processes whose time scales reflect the modulation frequency of the radiation. The heating and cooling processes lead to expansions and contractions of the gas, causing sound waves with the modulation frequency. These can be measured using, for example, sound detectors and/or flow detectors. The power of the sound waves is preferably directly proportional to the concentration of the absorbing gas.

In a further preferred embodiment, the MEMS sensor is a MEMS filter, preferably a MEMS frequency filter, in particular a SAW or BAW filter. A SAW filter is preferably a surface acoustic wave filter, which is in particular a bandpass filter for electrical signals. BAW (bulk acoustic wave) filters are preferably similar electronic filters with bandpass characteristics. However, unlike SAW filters, these preferably exhibit a base substrate in which the acoustic waves propagate.

In preferred embodiments, the semiconductor component comprises a MEMS element. In further preferred embodiments, the semiconductor component comprises an electronic circuit. In further preferred embodiments, the semiconductor component comprises a MEMS element and an electronic circuit.

In a preferred embodiment, the semiconductor component is characterized in that the electronic circuit is selected from a group comprising a computing unit, a processor, a microprocessor, an integrated circuit (IC), an application specific integrated circuit (ASIC), a programmable logic device (PLD), a field programmable gate array (FPGA) and/or a programmable logic device.

In a further aspect, the invention relates to a method for producing a semiconductor component comprising the following steps:
a) Provision of a base substrate
b) Attachment of a MEMS device and/or an electronic circuit on or in the base substrate, characterized in that the base substrate comprises a concrete material, an insulating layer comprising a concrete material is applied to insulate an electrical connection and/or a protective enclosure comprising concrete material is applied, which at least partially encloses the MEMS device and/or the electronic circuit.

The average person skilled in the art will recognize that technical features, definitions, advantages and preferred embodiments for the semiconductor component according to the invention also apply to a method for producing the semiconductor component and vice versa.

The preferred method for producing the semiconductor component advantageously achieves a significant improvement to the process, as the self-hardening property of the concrete material in particular can be utilized. Self-hardening can already take place at room temperature, for example. This means that it is not necessary to integrate further process steps in order to harden the concrete material and thus carry out the final shaping. This advantageously reduces the complexity of the method and saves costs, as concrete material, for example, is more cost-effective than using a furnace to carry out drying and/or hardening. For example, the concrete material can be introduced as a paste, taking into account a desired shape, in order to then dry independently.

Concrete material solidifies not only through drying in itself, but also through the chemical process of setting. The cement and the water in the concrete material can preferably form a cement paste that crystallizes and bonds firmly with other constituent elements of the concrete. In the concrete material, the evaporation of the water is preferably not relevant for hardening and only occurs partially. Instead, water remains in the concrete material due to the setting process and is important for its strength. During the setting process, hardening takes place due to the binder, which in the case of concrete material is cement. Particularly in view of the fact that the dimensions of semiconductor components in semiconductor and/or microsystem technology are many times smaller compared to the usual use of concrete material, the self-hardening of the concrete material can be utilized efficiently in order to obtain finished semiconductor components advantageously quickly, in particular in the context of mass production. A particular advantage is that concrete material can be used in processing at temperatures below a critical temperature that could have a detrimental effect on constituents of the semiconductor component. In particular, a sufficiently reliable shaping of constituents of the semiconductor component, e.g. MEMS structures for providing the MEMS element, is ensured. Furthermore, the self-hardening of the concrete material can advantageously take place at temperatures that are below temperature ranges that could be critical for constituents and/or materials of the semiconductor component. Thus, self-hardening is advantageously possible at temperatures between 20 °C-100 °C, preferably between 20 °C-80 °C, particularly preferably between 30 °C-60 °C. In particular, self-hardening can advantageously take place at room temperature. It is of particular advantage that an external energy supply is not necessary for hardening and/or solidification.

Furthermore, it is advantageous that the concrete material can be combined with a variety of functional materials, in particular to cause a chemical reaction that can generate constituents of the semiconductor component, such as metallization for the generation of electrical connections. The alkaline property of the concrete material must be taken into account here, but this can also be used to advantage, as hydroxide ions are present as active ions and enable rapid bonding and/or reaction.

Advantageously, concrete material is also particularly easy to process, for example in order to obtain a desired shape and/or structure. This makes it particularly easy to form MEMS structures in the base substrate in order to provide the MEMS element. In particular, shapes and/or structures can be configured by means of a method by which the concrete material for a constituent of the semiconductor component can be produced.

In a preferred embodiment, the method is characterized in that the concrete material is applied and/or processed by a method selected from a group comprising tape casting, injection molding, additive manufacturing, embossing and/or joining, wherein preferably a pore structure and/or a roughness can be adjusted by selection of the parameters of the method.

Concrete material can be advantageously used in a range of production methods that are used in the context of semiconductor and/or microsystems technology to produce semiconductor components. The aforementioned methods have proven effective in the prior art and ensure optimum operation and substantially error-free production of semiconductor components. Advantageously, the aforementioned methods can also be used to reliably adjust the shaping and/or structure of the concrete material for one or more constituents of the semiconductor component.

Tape casting is a primary molding method that can be used to produce thin and/or large-area foils comprising concrete material. The concrete material preferably flows from a storage container with an adjustable slot at the bottom under a drum (drum casting) or an endless copper belt (belt casting) without pressure or bubbles. The concrete material can preferably also be spread evenly with an adjustable blade. Process parameters can be monitored particularly easily and reliably during tape casting. Foils comprising concrete material that have been provided by tape casting are advantageously characterized by a very homogeneous surface that is free of air bubbles and shrinkage.

Injection molding is also a primary molding method. The concrete material is injected under pressure into a mold, the injection mold, using an injection molding machine. In the injection mold, the concrete material returns to a solid state through cooling or a cross-linking reaction and is removed as a finished part after the injection mold is opened.

Additive manufacturing comprises production methods in which the material comprising concrete material is applied layer by layer to provide three-dimensional objects. The layer-by-layer build-up is computer-controlled according to one or more predefined dimensions and/or shapes. Physical and/or chemical hardening and/or melting processes take place during the build-up.

During embossing, the surface of the concrete material is processed using dies in order to obtain desired structures, such as pores, reliefs, depressions, cavities, etc. Embossing can preferably also be used to correct dimensional and/or shape deviations of a constituent of the semiconductor component.

Joining refers to general methods by which at least two constituents of the semiconductor component can be permanently connected (joined). In the context of semiconductor and/or microsystems technology, this includes in particular welding, soldering, gluing and/or assembly and joining techniques, such as bonding.

Whereas in the prior art, concrete materials are generally only used for macroscopic components, it was recognized in accordance with the invention that extremely delicate structures can also be provided, in particular using the aforementioned primary molding methods, which allow the production of a semiconductor component comprising structures and/or constituents in the micrometer range

In a preferred embodiment, the method is characterized in that the concrete material is applied in paste-like form, preferably utilizing self-hardening of the concrete material by an exothermic reaction.

A paste-like form of the concrete material means that the concrete material is present as a paste, i.e. as a solid-liquid mixture. The concrete material as a paste can be characterized by the solid content and/or the viscosity. The concrete material in the form of a paste preferably comprises a solid content of between 30 %-80%, preferably between 50 %-70%. Particularly preferred is a solid content of more than 50%. Preferably, the concrete material in its past-like state exhibits a viscosity of between 1-3000 mPa s (millipascal-seconds), preferably between 1-1000 mPa s, particularly preferably between 1-500 mPa s, most preferably between 1-200 mPa s. In particular, the paste is characterized in that it is preferably not flowable, but spreadable.

Preferably, the self-hardening of the concrete material is utilized to provide the semiconductor component and/or constituents of the semiconductor component. In particular, hydration takes place, i.e. the addition of water molecules. In particular, the hydration of calcium oxide, magnesium oxide and/or cement to calcium hydroxide, magnesium hydroxide and/or calcium silicate hydrates is relevant for the use of concrete material. Without being limited to theory, the setting process on which the self-hardening of the concrete material is based is an exothermic reaction.

In a preferred embodiment, the method is characterized in that the base substrate comprises a material comprising concrete and the base substrate comprises an additive, wherein preferably the additive is activated by an ablation process such that active regions are formed and the active regions are utilized by means of metallization to provide an electrical connection for the MEMS component, wherein preferably the electrical connection, preferably a conductor path, is introduced by a galvanic process.

The additive can preferably be selected from a group comprising aluminosilicates, preferably tectoaluminosilicates. Through activation, the additive exhibits a state in which a reaction or type of reaction can take place at a higher rate or yield. The use of an ablation process has proven to be a particularly reliable method of activating the additive. Activation of the additive can advantageously enable a reliable connection with the material for metallization, for example to provide electrical connections, preferably conductor paths. Preferably, the metallization is carried out by a galvanic process.

The galvanic process uses an electric current to dissolve a metal in a bath containing an electrolyte, starting from a positive pole (anode) and transferring it to the negative pole (cathode). The metal ions dissolved in the bath are deposited on the activated regions by reduction, preferably by making electrical contact with the negative pole. Alternatively, the metal ions can already be contained in the electrolyte as a solution. A galvanic process advantageously allows the metal ions to be deposited particularly evenly, such that homogeneous electrical connections can be created in terms of structure.

In a further aspect, the invention relates to the use of a concrete material for the production of a semiconductor component.

The inventors have recognized that concrete material can be used in the context of semiconductor and/or microsystem technology, which has an advantageous effect on the structure and the production method for semiconductor components. In this context, one or more constituents of the semiconductor component may comprise concrete material, such as the base substrate, an insulating layer and/or a protective enclosure. Concrete material is also extremely well suited to being integrated into prior art methods for producing semiconductor components. Consequently, the use of concrete material in the production of a semiconductor component represents a significant improvement over the prior art. Such use of concrete materials was not previously known in the prior art.

### REFERENCES

Fedder, Gary K. “MEMS fabrication.” International Test Conference, 2003, Proceedings. ITC 2003. IEEE Computer Society, 2003.

Rahman, Md Atikur. “A review on semiconductors including applications and temperature effects in semiconductors.” American Academic Scientific Research Journal for Engineering, Technology, and Sciences 7.1 (2014): 50-70

Shamiryan, Denis, et al. “Low-k dielectric materials.” Materials today 7.1 (2004): 34-39.

Park, Heakyoung. “Sealing dispensing requirements to meet MEMS packaging and throughput impact.” Additional Papers and Presentations 2013. DPC (2013): 000535-000570

1. A semiconductor component comprising a MEMS element and/or an electronic circuit, wherein the MEMS element and/or the electronic circuit is provided on or in a base substrate, wherein the base substrate comprises a concrete material, the semiconductor component exhibits an insulating layer comprising concrete material for insulating an electrical connection and/or the MEMS device and/or the electronic circuit is at least partially enclosed by a protective enclosure comprising concrete material.

2. The semiconductor component according to the claim 1, wherein the concrete material exhibits a cement.

3. The semiconductor component according to claim 1, wherein the concrete material is a fiber-reinforced concrete comprising fibers.

4. The semiconductor component according to claim 1, wherein the concrete material exhibits a pore structure.

5. The semiconductor component according to claim 1, wherein the concrete material exhibits a roughness, wherein the roughness exhibits an average roughness value in a range between 0.01 μm and 100 μm.

6. The semiconductor component according to claim 1, wherein the base substrate exhibits a concrete material and an additive.

7. The semiconductor component according to claim 1, wherein the insulating layer exhibits a concrete material.

8. (canceled)

9. The semiconductor component according to claim 1, wherein the semiconductor component exhibits a protective layer comprising concrete material.

10. The semiconductor component according to claim 1, wherein the semiconductor component exhibits a capping substrate comprising concrete material, wherein the capping substrate covers the MEMS device and is materially bonded to the base substrate.

11. The semiconductor component according to claim 1, wherein the MEMS element is selected from the group consisting of acoustic MEMS transducers, optical MEMS transducers, MEMS sensors, MEMS gas sensors and MEMS filters and/or wherein the electronic circuit is selected from the group consisting of a computing unit, a processor, a microprocessor, an integrated circuit (IC), an application-specific integrated circuit (ASIC), a programmable logic device (PLD), a field programmable gate array (FPGA) and a programmable logic controller.

12. A method for producing a semiconductor component according to claim 1 comprising the following steps:
providing a base substrate, and
attaching a MEMS device and/or an electronic circuit on or in the base substrate,
wherein the base substrate comprises a concrete material, an insulating layer comprising a concrete material is applied to insulate an electrical connection and/or a protective enclosure comprising concrete material is applied, which at least partially encloses the MEMS device and/or the electronic circuit.

13. The method according to claim 12, wherein the concrete material is applied and/or processed by a method selected from the group consisting of tape casting, injection molding, additive manufacturing, embossing and joining.

14. The method according to claim 12, wherein the concrete material is applied in paste form, wherein the self-hardening property of the concrete material is utilized by means of an exothermic reaction.

15. The method according to claim 12, wherein the base substrate exhibits a material comprising concrete and the base substrate exhibits an additive, wherein the additive is activated using an ablation process, such that active regions are formed and the active regions are utilized by means of metallization to provide an electrical connection for the MEMS device.

16. Semiconductor component according to claim 4, wherein the pore structure exhibits pores with a diameter selected between 1 nm-200 nm

17. The semiconductor component according to claim 6 wherein the additive can be activated by an ablation process to form active regions and the active regions can be utilized by means of metallization to provide for the electrical connection of the MEMS element and/or the electronic circuit.

18. The semiconductor component according to claim 7 wherein the insulating layer is at least partially present on the electrical connection and/or encases an electrical connection or wherein the insulating layer exhibits a pore structure.

19. The semiconductor component according to claim 9 wherein the protective layer is present in a surface-conformal manner on the MEMS element and/or the electronic circuit.

20. The method according to claim 12 wherein a pore structure and/or a roughness can be adjusted by selecting parameters of the method or the electrical connection is introduced by means of a galvanic process.
